(19) United States
(12) Patent Application Publication
(10) Pub. No.: US 2004/0166657 A1
(43) Pub. Date: Aug. 26, 2004

(54) Semiconductor device and its manufacturing method

(76) Inventor: Makoto Hasegawa, Mie (JP)

Correspondence Address: Finnegan, Henderson, Farabow,, Garrett & Dunner, L.L.P., 1300 I Street, N.W., Washington, DC, 20005-3315, US

(21) Appl. No.: 10/736,578

(22) Filed: Dec. 17, 2003

(30) Foreign Application Priority Data
Dec. 18, 2002 (JP) 2002-367110

(51) Int. Cl. H01L 21/44

(52) U.S. Cl. 438/597

(57) ABSTRACT

A semiconductor device comprises a substrate having an electrically conducting portion; a plurality of wirings lying above the electrically conducting portion and insulated from the electrically conducting portion; a first top protection layer formed on the top surface of each said wiring; a second top protection layer made of a material higher in etching rate than the first top protection layer, said second top protection layer being formed on the top surface of each said first top protection layer; a side protection film formed on each side surface of the first top protection layer, the second protecting layer and said wiring; an inter-layer insulation film made of a material with a higher etching rate than the first top protection layer, said inter-layer insulation film filling a space between the wirings and covering the second top protection layers; and a contact hole penetrating the inter-layer insulation film between the wirings and reaching said electrically conducting portion, said contact hole having step portion formed on inner walls of said contact hole due to projections of the side protection films.

### CROSS-REFERENCE TO RELATED APPLICATION

This application is based upon and claims the benefit of priority from the prior Japanese Patent Application No. 2002-367110, filed on Dec. 18, 2002, the entire contents of which are incorporated herein by reference.

### BACKGROUND OF THE INVENTION

1. Field of the Invention

This invention relates to a semiconductor device and its manufacturing method.

2. Related Background Art

The distance between wirings used in semiconductor devices is becoming narrower and narrower along with microminiaturization of semiconductors. In order to form contacts between narrow wirings to connect to conductors underlying the wirings, SACs (self-aligned contacts) have been used. For example, SACs are frequently used as contacts passing between adjacent word lines without contacting them for connection to a semiconductor device underlying the word lines.

FIGS. 4A and 4B are cross-sectional views of word lines and their periphery of conventional DRAM 200. FIG. 4A shows an aspect before contacts holes for SACs are formed. A plurality of word lines 20 are formed on the top surface of a semiconductor substrate 10. Each word line 20 is composed of two different layers, namely, polysilicon layer 22 and silicide layer 24. A top protection layer 30 is formed on the top surface of each word line 20, and thin thermal oxide films 40 are formed on side surfaces of each word line 20. Side protection films 50 are formed on side surfaces of each word line 20 and side surfaces of each top protection film 30 to cover the thermal oxide films 40. Furthermore, an inter-layer insulation film 60 is deposited on the semiconductor substrate 10 to fill in the area between adjacent side protection films 50. A photo-resist 70 is formed on the top surface of the inter-layer insulation film 60 and patterned by photolithography.

FIG. 4B shows an aspect after formation of contact holes 80 for SACs. The inter-insulation film 60 is anisotropically etched by RIE (reactive ion etching), for example. The inter-layer insulation film 60 is made of a material having a higher etching rate than the top protection layer 30 and the side protection layer 50. Therefore, the inter-layer insulation film 60 can be etched in self-alignment along the side protection films 50 down to the top surface of the substrate 10. As a result, the contact holes 80 are formed to extend from the top surface of the inter-layer insulation film 60, passing between adjacent word lines 20 and reaching the semiconductor substrate 10.

Thereafter, the photo resistor 70 is removed, and a conductor material for contact fills in the contact hole. Thereby, SACs (not shown) connecting to the top surface of the semiconductor substrate 10 between adjacent word lines 20 are completed.

Since the top protection layers 30 and the side protection films 50 have a slower etching rate than the inter-layer insulation film 60, they can function as etching stoppers for protecting the word lines 20. Therefore, SACs filling in the contact holes 80 will not short circuit with the word lines 20.

However, edges of the top protection layers 30 and the side protection films 50 are physically weak and subject to erosion by anisotropic etching. Therefore, the top protection layers 30 and/or the side protection films 50 covering upper edges of the word lines 20 are thinned. If the top protection layers 30 and the side protection films 50 become significantly thin, the conductor in the contact holes 80 will short circuit with the word lines 20.

This has created a demand for a semiconductor device in which SACs connecting to the semiconductor substrate between adjacent wirings are prevented from short-circuiting with the wirings.

### SUMMARY OF THE INVENTION

A semiconductor device comprises a substrate; a plurality of wirings mounted on the substrate; a top protection layer mounted on a top surface of each the wiring; a side protection film mounted on each side surface of the top protection layer; an inter-layer insulation filling a space between the wirings and covering the top protection layer; and a contact hole penetrating the inter-layer insulation film between the wirings and reaching the substrate, the contact hole having a edge portion on inner wall of the contact hole, the edge portion being in a level higher than above the wirings and projecting upward away from the substrate in a position.

A semiconductor device comprises a substrate having an electrically conducting portion; a plurality of wirings lying above the electrically conducting portion and insulated from the electrically conducting portion; a first top protection layer formed on the top surface of each said wiring; a second top protection layer made of a material higher in etching rate than the first top protection layer, said second top protection layer being formed on the top surface of each said first top protection layer; a side protection film formed on each side surface of the first top protection layer, the second protecting layer and said wiring; an inter-layer insulation film made of a material with a higher etching rate than the first top protection layer, said inter-layer insulation film filling a space between the wirings and covering the second top protection layers; and a contact hole penetrating the inter-layer insulation film between the wirings and reaching said electrically conducting portion, said contact hole having step portion formed on inner walls of said contact hole due to projections of the side protection films.

A manufacturing method of a semiconductor device, comprises forming a plurality of wirings on a substrate; forming first top protection layers protecting top surfaces of the wirings; forming second top protection layers on the top surfaces of the first top protection layers, said second top protection layers being higher in etching rate than the first top protection layers; forming side protection films on each side surfaces of the wirings, the first top protection layers and the second top protection layers; depositing an inter-layer insulation film to fill between adjacent said wirings and to cover the second top protection layers, said inter-layer insulation film being made of a material higher in etching rate than the first top protection layers; and locally etching the inter-layer insulation film between adjacent said wirings in substantial self-alignment by using the second top protection layers and the side protection film.

### BRIEF DESCRIPTION OF THE DRAWINGS

FIG. 1 is a cross-sectional view of DRAM 100 according to an embodiment of the invention;

FIG. 2A is a diagram showing a manufacturing method of DRAM 100;

FIG. 2B is a diagram showing a process next to FIG. 2A of the manufacturing method of DRAM 100;

FIG. 2C is a diagram showing a process next to FIG. 2B of the manufacturing method of DRAM 100;

FIG. 3A is a diagram showing a process next to FIG. 2C of the manufacturing method of DRAM 100;

FIG. 3B is a diagram showing a process next to FIG. 3A of the manufacturing method of DRAM 100;

FIG. 3C is a diagram showing a process next to FIG. 3B of the manufacturing method of DRAM 100;

FIG. 4A is a cross-sectional view of a part of DRAM 200 including word lines; and

FIG. 4B is a cross-sectional view of the same part of DRAM 200 under a process next to FIG. 4A.

### DETAILED DESCRIPTION OF THE INVENTION

An embodiment of the invention will now be explained below with reference to the drawings. The embodiment, however, should not be construed to limit the invention.

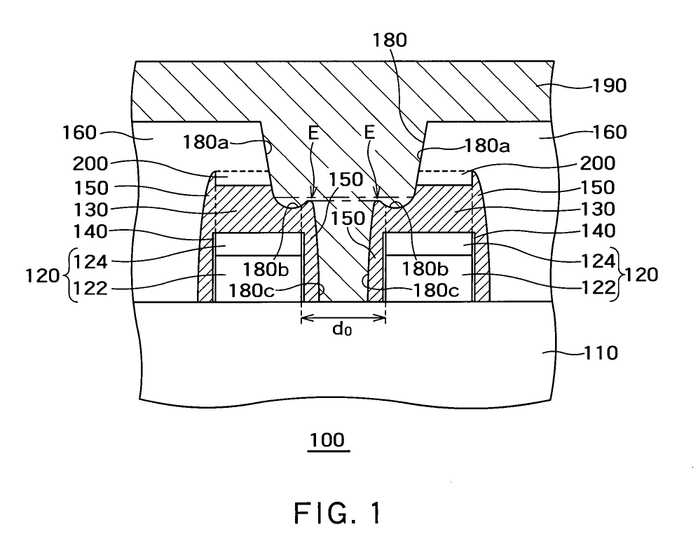

FIG. 1 is a cross-sectional view of DRAM 100 according to an embodiment of the invention. A plurality of word lines 120 are mounted on the top surface of a semiconductor substrate 110. For better understanding of the embodiment, FIG. 1 shows two adjacent word lines 120. In this embodiment, each word line 120 is composed of two different layers, namely, polysilicon layer 122 and silicide layer 124. A first top protection layer 130 is mounted to cover the top surface of each word line 120. Thin thermal oxide films 140 are mounted to cover the side surfaces of each word line 120. A second top protection layer 200 is mounted to cover the top surface of the first protection layer 130. Side protection films 150 are mounted to cover the side surfaces of each word line 120, the side surfaces of the first top protection film 130 and the side surfaces of the second top protection film 200. The upper end of side protection film 150 is higher than the top surface of first top protection layer 130. Furthermore, an inter-layer insulation film 160 is mounted to cover the second protection film 200 and the side protection films 150.

Moreover, a contact hole 180 is formed in self-alignment between two adjacent word lines 120. A conductor 190 is filled in the contact hole 180 to connect to a semiconductor substrate 110. Hereunder, each contact hole 180 and the conductor 190 in combination are called SAC (self-aligned contact) 180, 190 as well.

Each contact hole 180 is composed of an upper opening portion 180a, a step portion 180b and a lower opening portion 180c. The upper opening portion 180a extends from the top surface of the inter-layer insulation film 160 to an intermediate level of the first top protection layer 130, and opens by a distance wider than the distance do between adjacent two word lines 120. The lower opening portion 180c is in communication with the upper opening portion 180a, and opens by a distance narrower than the distance do. The lower opening portion 180c reaches to the semiconductor substrate 110. The step portion 180b is formed between the upper opening portion 180a and the lower opening portion 180c. In the step portion 180b, edges' E of the side protection films 150 project upward away from the top surface of the semiconductor substrate 110 and is a level higher than above the wirings. FIG. 1 shows the boundary between the upper opening portion 180a and the step portion 180b and the boundary between the step portion 180b and the lower opening portion 180c by dot-and-dash lines.

To form the contact hole 180 in self-aligned manner, the first top protection layer 130 and the side protection films 150 have lower etching rates than the inter-layer insulation film 160 and the second top protection layer 200. In other words, a ratio of the etching rate of the inter-layer insulation film 160 and the second top protection layer 200 with respect to the etching rate of the first top protection layer 130 and the side protection films 150 (selectivity) is larger than 1.

The first top protection layer 130 and the side protection films 150 may be made of different materials, but they are preferably made of the same material. For example, both the first top protection layer 130 and the side protection films 150 may be silicon nitride films. If the first top protection layer 130 and the side protection films 150 are silicon nitride films, they can be joined integrally by annealing after forming the first top protection layer 130 and the side protection films 150. Therefore, as shown in FIG. 1, the boundary between the first top protection layer 130 and the side protection films 150 is represented by a broken line.

The inter-layer insulation film 160 and the second top protection layer 200 may be made of different materials, but they are preferably made of the same material. For example, both of the inter-layer insulation film 160 and the second top protection layer 200 may be TEOS (Si(OC₂H₅)₄) or BRSG. If the inter-layer insulation film 160 and the second top protection layer 200 are made of the same material, they can be joined integrally by annealing after forming the inter-layer insulation film 160 and the second top protection layer 200. Therefore, as shown in FIG. 1, the boundary between the inter-layer insulation film 160 and the second top protection layer 200 is represented by a broken line.

The conductor 190 is made of an electrically conductive material such as doped silicon or metal.

According to the instant embodiment, the ends E of the side protection films 150 project upward in the step portion 180b of the contact hole 180 away from the semiconductor substrate as shown in FIG. 1. As a result, upper edges of the word lines 120 nearer to the center of the contact hole 180 are covered thicker by the side protection films 150 and the first top protection layer 130 than in conventional devices. It is therefore possible to reliably prevent SAC 180, 190 from short-circuiting with the word line 120.

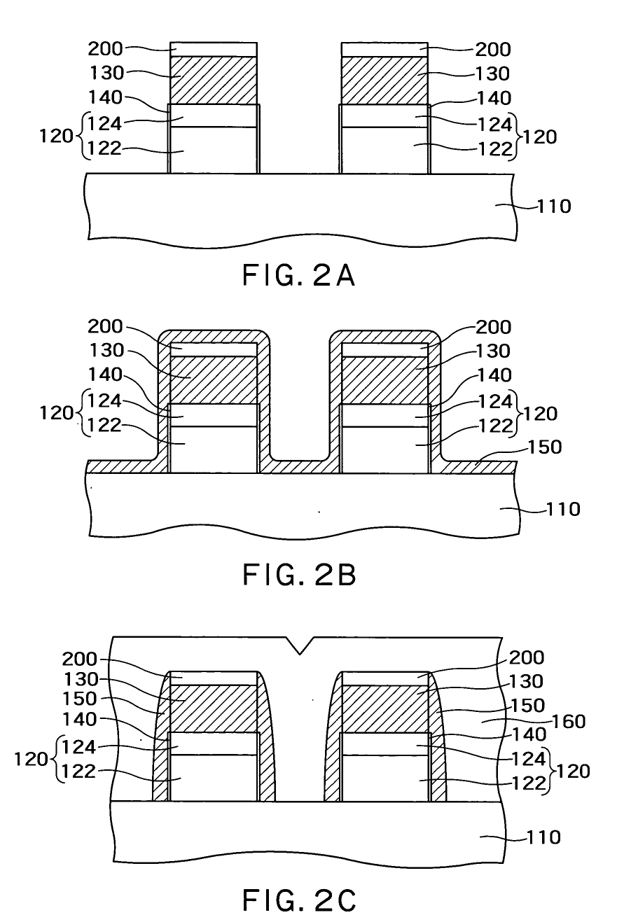

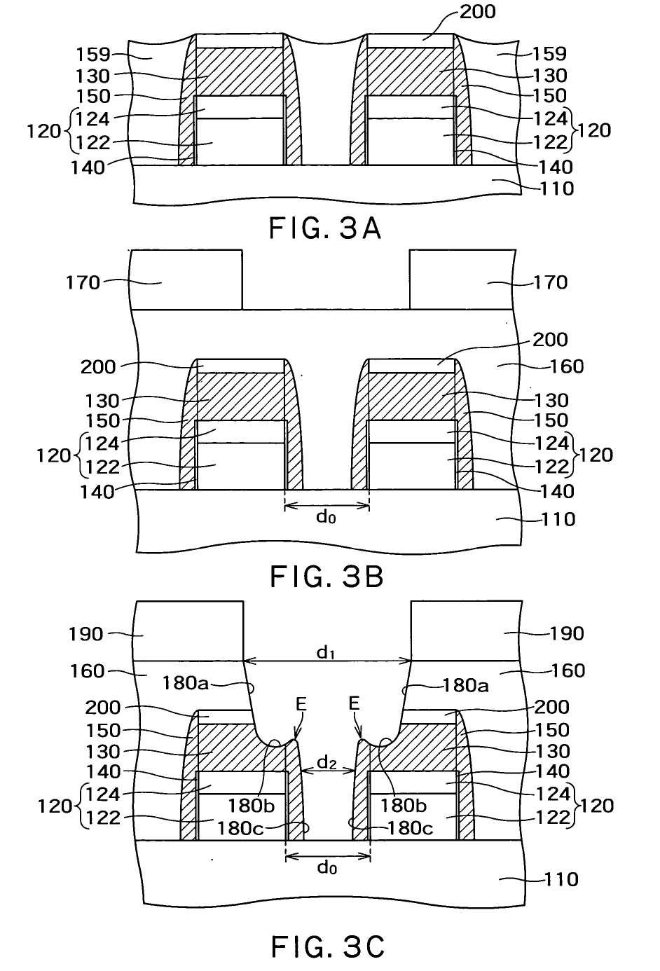

FIGS. 2A through 3C are diagrams showing a manufacturing method of DRAM 100 according to the embodiment in the order of its process steps. Here is omitted illustration of a diffusion layer to be formed on the top surface of the semiconductor substrate 110.

First, the polysilicon layer 122 is deposited on the top surface of the semiconductor substrate 110. The silicide layer 124 is next formed on the polysilicon layer 122. Then, a silicon nitride film is deposited as the top protection layer 130 on the silicide layer 124. Further, the second top protection layer 200 of TEOS or BPSG is deposited on the first top protection layer 130.

Subsequently, the first top protection layer 130 and the second top protection layer 200 are patterned by photolithography and RIE. Thereafter, using the first top protection layer 130 and the second protection layer 200 as a mask, the polysilicon layer 122 and the silicide layer 124 are patterned. As a result, the word lines 120, the first top protection layers 130 and the second top protection layer 200 are made out as shown in FIG. 2A. After that, the word lines 120 are oxidized to form the thin thermal oxide layers 140 on side surfaces of the word lines 120.

As shown in FIG. 2B, a silicon nitride film is deposited as the side protection film 150.

Subsequently, the side protection film 150 is anisotropically etched by RIE or another appropriate technique. Thereby, the side protection films 150 are formed on side surfaces of the word lines 120, first top protection layers 130 and second top protection layers 200 as shown in FIG. 2C. Since the second protection layers 200 overlie the first top protection layers 130, side protection films 150 are formed to stand higher than the top surface of the first top protection layers 130. The side protection films 150 are used, not only to protect side surfaces of the word lines 120, but also to function as spacers when LDDs (lightly diffused drains) (not shown) are formed in the semiconductor substrate 110.

In the next step, TEOS or BPSG is deposited as the inter-layer insulation film 160 to bury the space between adjacent word lines 120.

As shown in FIG. 3A, the top surface of the inter-layer insulation film 160 is planarized by CMP, for example.

As shown in FIG. 3B, deposition of TEOS or BPSG is resumed. As a result, the inter-layer insulation film 160 having the planarized top surface and fully covering the second top protection layer 200 is obtained. Thereafter, a photo resist is coated on the top surface of the inter-layer insulation film 160, and patterned by lithography to form a photo resist layer 170. The photo resist layer 170 locally exposes the top surface of the inter-layer insulation film 160 between adjacent word lines by a width larger than the distance do between the word lines.

As shown in FIG. 3C, the inter-layer insulation film 160 is next etched by RIE using the photo resist layer 170 as a mask. This etching process is explained in greater detail with reference to FIG. 1. In this etching process, the inter-layer insulation film 160 and the second top protection layer 200 are etched following the pattern of the photo resist layer 170 to make a hole of a width d₁ wider than the distance do between adjacent word lines.

As already explained, the etching rate of the inter-layer insulation film 160 is higher than those of the first top protection layers 130 and the side protection layers 150. Therefore, after the etching progresses to the fist top protection layers 130 and the side protection films 150, the inter-layer insulation film 160 is etched along the side of the side protection layers 150. That is, the inter-layer insulation film 160 is etched to make a hole of a width d₂ narrower than the distance do between adjacent word lines, after the etching progresses to the fist top protection layers 130 and the side protection films 150. When the inter-layer insulation film 160 is etched to the depth locally exposing the top surface of the semiconductor substrate 110, the contact hole 180 is obtained.

In this etching process, although the first top protection layers 130 and the side protection layers 150 have an etching rate lower than the etching rate of the inter-layer insulation film 160, the first top protection layers 130 and the side protection layers 150 are etched as well to a certain extent. However, since the side protection films 150 extend higher than the top surfaces of the first top protection layers 130, projections E remain after the contact hole 180 is formed.

In the next process, doped polysilicon 190 is filled in the contact hole 180, and it is patterned to obtain DRAM 100 shown in FIG. 1.

The etching process for forming the contact hole 180 may be the same as that of the conventional technique. Since the side protection films 150 project higher than the top surface of the first top protection layers 130, the etching process identical to the conventional etching technique can be used to reliably cover the upper end portions of the word lines 120 thicker by the first top protection layers 130 and the side protection films 150. As a result, the embodiment can reliably prevents a short circuit between the word lines 120 and SAC 180, 190.

The embodiment has been explained by way of DRAM; however, the invention is applicable to other products using SACs.

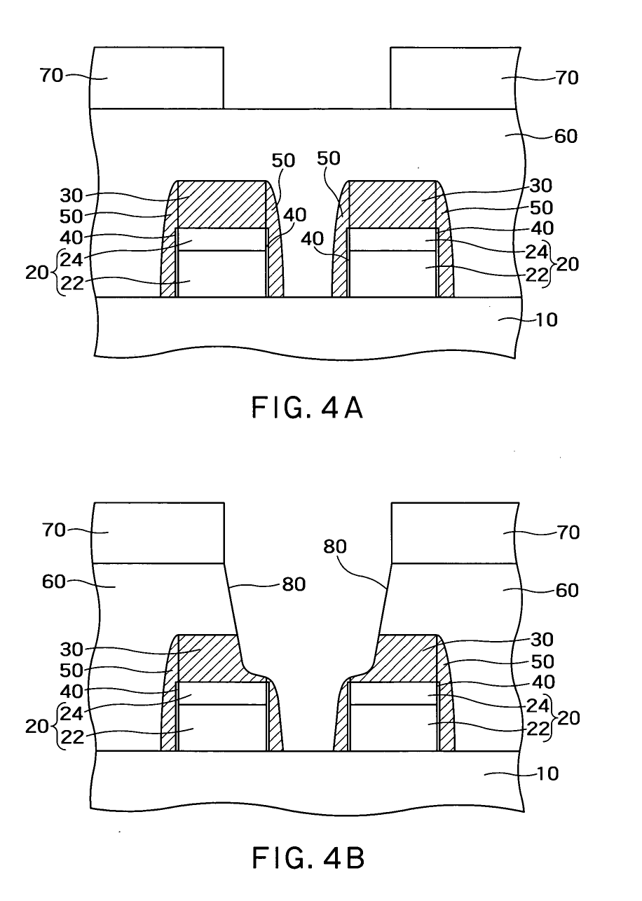

To cope with problems involved in the conventional technique, it may seem effective to increase the thickness of the top protection layer 30 shown in FIG. 4. However, the top protection layer 30 will become difficult to process. Additionally, since the ratio of the height of the side protection films 50 relative to the distance between adjacent word lines 20 (also called the aspect ratio hereinafter) increases, residue of the etching is liable to remain on the bottom of the contact hole 80. If the etching duration is extended to remove the residue, then the upper end portions of the top protection layers 30 will become as thin as those of the conventional technique.

To cope with problems involved in the conventional technique, it may seem effective to increase the ratio of the etching rate of the inter-layer insulation film 60 relative to the etching rate of the top protection layers 30 and the side protection films 50. In this case, however, the top protection layer 30 and the side protection films 50 will become difficult to process.

Furthermore, if those two methods are employed in combination, there occurs the problem that conditions for etching in the etching process must be changed upon forming the contact hole 80.

As such, the semiconductor device according to the embodiment of the invention can reliably prevent SACs connecting to the semiconductor substrate between adjacent wirings from short-circuiting with the wirings.

What is claimed is:

1. A semiconductor device comprising:
a substrate;
a plurality of wirings mounted on the substrate;
a top protection layer mounted on a top surface of each the wiring;
a side protection film mounted on each side surface of the top protection layer;
an inter-layer insulation filling a space between the wirings and covering the top protection layer; and
a contact hole penetrating the inter-layer insulation film between the wirings and reaching the substrate, the contact hole having a edge portion on inner wall of the contact hole, the edge portion being in a level higher than above the wirings and projecting upward away from the substrate in a position.

2. The semiconductor device according to claim 1, wherein an upper edge of the side protection film of non-contact hole side is higher than a top surface of the top protection layer.

3. A semiconductor device comprising:
a substrate having an electrically conducting portion;
a plurality of wirings lying above the electrically conducting portion and insulated from the electrically conducting portion;
a first top protection layer formed on the top surface of each said wiring;
a second top protection layer made of a material higher in etching rate than the first top protection layer, said second top protection layer being formed on the top surface of each said first top protection layer;
a side protection film formed on each side surface of the first top protection layer, the second top-protection layer and said wiring;
an inter-layer insulation film made of a material with a higher etching rate than the first top protection layer, said inter-layer insulation film filling a space between the wirings and covering the second top protection layer; and
a contact hole penetrating the inter-layer insulation film between the wirings and reaching said electrically conducting portion, said contact hole having a step portion formed on inner walls of said contact hole due to projections of the side protection films.

4. The semiconductor device according to claim 3, wherein the contact hole includes:
an upper opening portion with a width wider than the distance between adjacent said wirings, and extending at least from the top surface of the inter-layer insulation film to top surfaces of the first top protection layers; and
a lower opening portion with a width narrower than the distance between adjacent said wirings and extending into communication with the upper opening portion and further reaching to the electrically conducting portion;
wherein said step portion is positioned between the upper opening portion and the lower opening portion.

5. The semiconductor device according to claim 4, wherein said step portion is formed by the side protection films, said side protection films being projected upward away from the top surface of the semiconductor substrate.

6. The semiconductor device according to claim 5, wherein the step portion is in a level higher than top surfaces of the wirings with respect to the top surface of the substrate.

7. The semiconductor device according to claim 3, wherein the contact hole is formed by locally removing the inter-layer insulation film between adjacent said wirings in substantial self-alignment with the side protection films.

8 The semiconductor device according to claim 3, wherein the first top protection layers and the side protection films are made of an identical material.

9. The semiconductor device according to claim 8, wherein the second top protection layers and the inter-layer insulation film are made of an identical material different from the material of the first top protection layers and the side protection films.

10. The semiconductor device according to claim 9, wherein the first top protection layers and the side protection films are silicon nitride films, and the second top protection layers and the inter-layer insulation film are made of TEOS or BPSG.

11. A manufacturing method of a semiconductor device, comprising:
forming a plurality of wirings on a substrate;
forming a first top protection layer protecting top surfaces of the wirings;
forming second top protection layers on the top surfaces of the first top protection layers, said second top protection layers being higher in etching rate than the first top protection layers;
forming side protection films on each side surfaces of the wirings, the first top protection layers and the second top protection layers;
depositing an inter-layer insulation film to fill a space between adjacent said wirings and to cover the second top protection layers, said inter-layer insulation film being made of a material higher in etching rate than the first top protection layers; and
locally etching the inter-layer insulation film between adjacent said wirings in substantial self-alignment by using the second top protection layers and the side protection film.

12. The manufacturing method according to claim 11, wherein in the process of etching the inter-layer insulation film, the inter-layer insulation film and the second top protection layers are locally removed by a width wider than the distance between adjacent said wirings, and the inter-layer insulation layer is locally removed next by a width narrower than the distance between adjacent said wirings along the side protection films.

13. The manufacturing method according to claim 11, wherein the etching of the inter-layer insulation film is isotropic etching.

14. The manufacturing method according to claim 12, wherein the etching of the inter-layer insulation film is isotropic etching.

15. The manufacturing method according to claim 11, wherein the first top protection layers and the side protection films are made of an identical material.

16. The manufacturing method according to claim 11, wherein the second top protection layers and the inter-layer insulation film are made of an identical material different from the material of the first top protection layers and the side protection films.

17. The manufacturing method according to claim 16, wherein the first top protection layers and the side protection films are silicon nitride films, and the second top protection layers and the inter-layer insulation film are made of TEOS or BPSG.
